(19) United States
(12) Patent Application Publication
(10) Pub. No.: US 2026/0269566 A1
(43) Pub. Date: Sep. 10, 2026

(54) LASER AND FABRICATION METHOD THEREFOR

(71) Applicant: HISENSE BROADBAND MULTIMEDIA TECHNOLOGIES CO., LTD., Qingdao (CN)

(72) Inventors: Fuli WANG, Qingdao (CN); Hongmin CHEN, Qingdao (CN)

(21) Appl. No.: 19/662,617

(22) Filed: Apr. 29, 2026

Related U.S. Application Data
(63) Continuation of application No. PCT/CN2024/074663, filed on Jan. 30, 2024.

(30) Foreign Application Priority Data
Oct. 31, 2023 (CN) 202311424689.6

(51) Int. Cl. H01S 5/12; H01S 5/042

(52) U.S. Cl. CPC H01S 5/1212; H01S 5/0421

(57) ABSTRACT

The present disclosure provides a laser and a fabrication method therefor. The laser includes a package cavity, and a gain chip, a wavelength selection assembly, and a reflector are disposed within the package cavity. The gain chip includes a top layer, a bottom layer, and a light-emitting layer. The light-emitting layer includes a first active region, a passive grating region, and a second active region, where the second active region can amplify a laser gain to increase output optical power.

The present disclosure is a continuation of International Application No. PCT/CN2024/074663, filed on January 30, 2024, which claims priority to Chinese Patent Application No. 202311424689.6, filed with the China National Intellectual Property Administration on October 31, 2023. All of the above-mentioned applications are incorporated herein by reference in their entirety.

### FIELD OF THE INVENTION

The present disclosure relates to the field of optical communication technology, and in particular, to a laser and a fabrication method therefor.

### BACKGROUND OF THE INVENTION

With an increasing demand for communication capacity, coherent optical modules utilize modulation modes such as quadrature amplitude modulation (QAM) to maximize the capacity of optical fibers. However, these modulation modes incur considerable insertion loss, thus requiring a tunable laser to output higher optical power.

### SUMMARY OF THE INVENTION

The present disclosure provides a laser and a fabrication method therefor.

According to a first aspect of the present disclosure, a laser is provided, including a package cavity, where the package cavity is internally provided with:

a gain chip, including:

a top layer, respectively including a first electrode region and a second electrode region, where a first electrical isolation trench is formed between the first electrode region and the second electrode region;

a bottom layer, including a third electrode region, where the third electrode region is electrically connected respectively to the first electrode region and the second electrode region to output carriers; and

a light-emitting layer, located between the top layer and the bottom layer, and including a light-emitting region, where the light-emitting region includes in sequence connected:

a first active region, located within a downward projection area of the first electrode region to receive the carriers, and configured to emit a broadband light beam according to injected carriers;

a passive grating region, located within a downward projection area of the first electrical isolation trench, including a grating region and a waveguide region, and configured to provide a first resonant end face for the laser; and

a second active region, located within a downward projection area of the second electrode region to receive the carriers;

a wavelength selection assembly, disposed outside the gain chip, located on one side close to the first active region, and configured to select light with a specific wavelength from the light beam emitted by the first active region; and

a reflector, disposed on one side, away from the gain chip, of the wavelength selection assembly, and configured to provide a second resonant end face for the laser, such that a resonant cavity is formed between the passive grating region and the reflector; and

the light beam emitted from the first active region is filtered by the wavelength selection assembly to select the light with the specific wavelength, the light with the specific wavelength oscillates in the resonant cavity to form laser, the laser is transmitted to the second active region through the passive grating region, and the second active region optically amplifies the laser according to the injected carriers.

According to a second aspect of the present disclosure, a fabrication method for a laser is provided, and applied to the laser provided in the first aspect of the present disclosure, where a gain chip is packaged within the laser, the fabrication method includes a fabrication method for the gain chip, and the fabrication method for the gain chip includes:

growing, in sequence from bottom to top, a buffer layer, a multi-quantum well structure layer, and a cover layer;

longitudinally etching downward from a local surface of the cover layer to a surface of the buffer layer to form a void region;

growing a passive structure on a surface of the void region, where the passive structure includes two layers of passive waveguides; fabricating a grating on a surface of the passive waveguide on an upper layer; then growing a grating cladding layer on a surface of the grating such that the grating cladding layer is flush with a surface of the cover layer;

etching downward from the surface of the cover layer to the surface of the buffer layer to respectively form the first active region, the passive grating region, and the second active region;

after forming sidewalls of the first active region, the passive grating region, and the second active region, growing sidewall current blocking layers on both sides; growing upward along surfaces of the first active region, the passive grating region, and the second active region until an upper confinement layer, a contact layer, and the top layer are in sequence formed; and continuing to grow along a bottom surface of the buffer layer until a lower confinement layer is formed;

etching downward along a projection area of the passive grating region on the top layer to form the first electrical isolation trench, where a first partition and a second partition are respectively formed on both sides of the first electrical isolation trench;

forming electrode windows on surfaces of the first partition and the second partition, and fabricating electrodes to respectively form a first electrode region and a second electrode region; and

fabricating electrodes on a bottom surface of the lower confinement layer to form the third electrode region.

### BRIEF DESCRIPTION OF THE DRAWINGS

To illustrate the technical solutions in the present disclosure more clearly, a brief introduction to the drawings used in some embodiments of the present disclosure will be provided below. Apparently, the drawings described below are merely the drawings in some embodiments of the present disclosure. Those of ordinary skill in the art can also derive other drawings from these drawings. Furthermore, the drawings described below can be regarded as schematic diagrams and are not intended to limit the actual dimensions of the products, the actual processes of the methods, or the actual timing of the signals involved in the embodiments of the present disclosure.

FIG. 1 is a partial architecture diagram of an optical communication system according to some embodiments of the present disclosure;

FIG. 2 is a partial structural diagram of a host computer according to some embodiments of the present disclosure;

FIG. 3 is a structural diagram of an optical module according to some embodiments of the present disclosure;

FIG. 4 is an exploded view of an optical module according to some embodiments of the present disclosure;

FIG. 5 is an internal structural diagram of an optical module according to some embodiments of the present disclosure;

FIG. 6 is an internal structural diagram of a tunable laser according to some embodiments of the present disclosure;

FIG. 7 is a structural diagram of a gain chip in a tunable laser according to some embodiments of the present disclosure;

FIG. 8 is a cross-sectional view of a gain chip in a tunable laser according to some embodiments of the present disclosure;

FIG. 9 is a schematic diagram of optical transmission of a tunable laser in a tunable laser according to some embodiments of the present disclosure; and

FIG. 10 is a schematic diagram of a fabrication process for a gain chip in a tunable laser according to some embodiments of the present disclosure.

### DETAILED DESCRIPTION OF THE EMBODIMENTS

In optical communication technology, in order to establish information transmission between information processing devices, it is necessary to load information onto light and use the propagation of light to achieve the transmission of information. Here, the light loaded with information is an optical signal. When the optical signal is transmitted in the information transmission devices, the loss of optical power can be reduced, such that high-speed, long-distance, and low-cost information transmission can be achieved. The signals that the information processing devices are able to recognize and process are electrical signals. The information processing devices usually include optical network units (ONUs), gateways, routers, switches, mobile phones, computers, servers, tablet computers, televisions, etc. The information transmission devices usually include optical fibers and optical waveguides.

The optical modules can achieve the conversion between optical signals and electrical signals from the information processing devices and the information transmission devices. For example, at least one of an optical signal input or an optical signal output of an optical module is connected to an optical fiber, and at least one of an electrical signal input or an electrical signal output of the optical module is connected to an optical network unit; a first optical signal from the optical fiber is transmitted to the optical module, and the optical module converts the first optical signal into a first electrical signal and transmits the first electrical signal to the optical network unit; and a second electrical signal from the optical network unit is transmitted to the optical module, and the optical module converts the second electrical signal into a second optical signal and transmits the second optical signal to the optical fiber. Since information can be transmitted through electrical signals between a plurality of information processing devices, at least one information processing device in the plurality of information processing devices is required to be directly connected to the optical module, and all information processing devices are not required to be directly connected to the optical module. Here, the information processing device directly connected to the optical module is referred to as a host computer of the optical module. In addition, the optical signal input or the optical signal output of the optical module can be referred to as an optical port, and the electrical signal input or the electrical signal output of the optical module can be referred to as an electrical port.

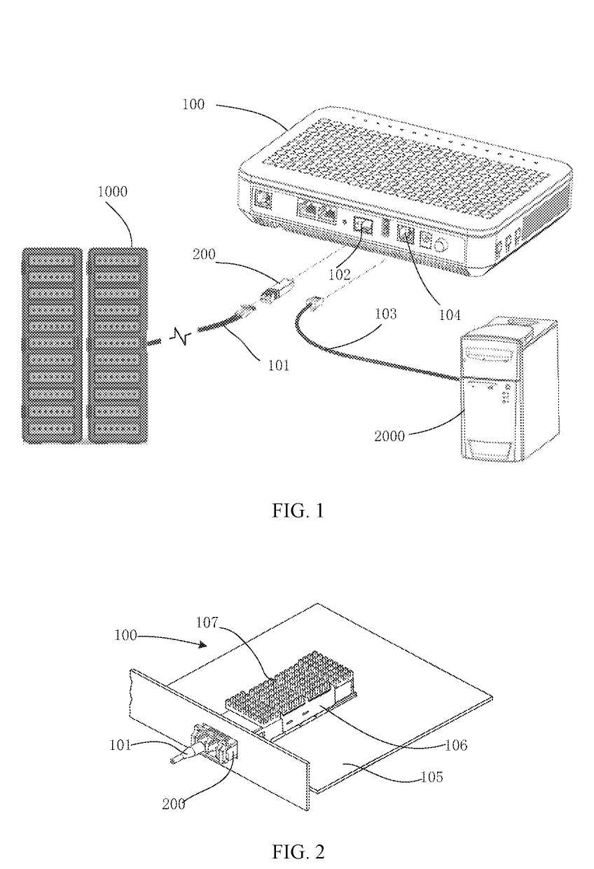

FIG. 1 is a partial architecture diagram of an optical communication system according to some embodiments of the present disclosure. As shown in FIG. 1, the optical communication system primarily includes a remote information processing device 1000, a local information processing device 2000, a host computer 100, an optical module 200, an optical fiber 101 and a network cable 103.

One end of the optical fiber 101 extends toward the remote information processing device 1000, and the other end of the optical fiber 101 is connected to the optical module 200 via an optical port of the optical module 200. An optical signal can undergo total reflection in the optical fiber 101, and the propagation of the optical signal in a total reflection direction can almost maintain its original optical power. The optical signal undergoes multiple total reflections in the optical fiber 101 to transmit an optical signal from the remote information processing device 1000 to the optical module 200 or to transmit an optical signal from the optical module 200 to the remote information processing device 1000, thereby implementing long-distance and low-power-loss information transmission.

The optical communication system may include one or more optical fibers 101, and the optical fiber 101 is detachably or fixedly connected to the optical module 200. The host computer 100 is configured to provide a data signal to the optical module 200, receive a data signal from the optical module 200, or monitor or control a working state of the optical module 200.

The host computer 100 includes a generally cuboid-shaped shell and an optical module interface 102 disposed on the shell. The optical module interface 102 is configured to be connected to the optical module 200, enabling the host computer 100 to establish a one-way or two-way electrical signal connection with the optical module 200.

The host computer 100 further includes an external electrical interface that can be connected to an electrical signal network. For example, the external electrical interface includes a universal serial bus (USB) interface or a network cable interface 104. The network cable interface 104 is configured to be connected to the network cable 103, enabling the host computer 100 to establish a one-way or two-way electrical signal connection with the network cable 103. One end of the network cable 103 is connected to the local information processing device 2000, and the other end of the network cable 103 is connected to the host computer 100, thereby establishing an electrical signal connection between the local information processing device 2000 and the host computer 100 via the network cable 103. For example, a third electrical signal sent by the local information processing device 2000 is transmitted to the host computer 100 via the network cable 103. The host computer 100 generates a second electrical signal according to the third electrical signal. The second electrical signal from the host computer 100 is transmitted to the optical module 200. The optical module 200 converts the second electrical signal into a second optical signal and transmits the second optical signal to the optical fiber 101. The second optical signal is transmitted through the optical fiber 101 to the remote information processing device 1000. For example, a first optical signal from the remote information processing device 1000 is transmitted through the optical fiber 101. The first optical signal from the optical fiber 101 is transmitted to the optical module 200. The optical module 200 converts the first optical signal into a first electrical signal, and then the optical module 200 transmits the first electrical signal to the host computer 100. The host computer 100 generates a fourth electrical signal according to the first electrical signal and transmits the fourth electrical signal to the local information processing device 2000. It should be noted that the optical module is a tool to achieve the conversion between optical signals and electrical signals. In the conversion between the optical signals and the electrical signals, the information remains unchanged, and the encoding and decoding methods for the information may vary.

In addition to the optical network unit, the host computer 100 further includes an optical line terminal (OLT), an optical network terminal (ONT), or a data center server.

FIG. 2 is a partial structural diagram of a host computer provided according to some embodiments of the present disclosure. To clearly show the connection relationship between the optical module 200 and the host computer 100, FIG. 2 shows only the structure of the host computer 100 related to the optical module 200. As shown in FIG. 2, the host computer 100 further includes a printed circuit board (PCB) 105 disposed in the shell, a cage 106 disposed on the surface of the PCB 105, a heat sink 107 disposed on the cage 106, and an electrical connector disposed inside the cage 106. The electrical connector is configured to be connected to the electrical port of the optical module 200. The heat sink 107 has protruding structures such as fins that enlarge the heat dissipation area.

The optical module 200 is inserted into the cage 106 of the host computer 100, and the optical module 200 is fixed by the cage 106. The heat generated by the optical module 200 is conducted to the cage 106 and then diffused through the heat sink 107. After the optical module 200 is inserted into the cage 106, the electrical port of the optical module 200 is connected to the electrical connector inside the cage 106, such that the optical module 200 establishes a two-way electrical signal connection with the host computer 100. In addition, the optical port of the optical module 200 is connected to the optical fiber 101, such that the optical module 200 establishes a two-way optical signal connection with the optical fiber 101.

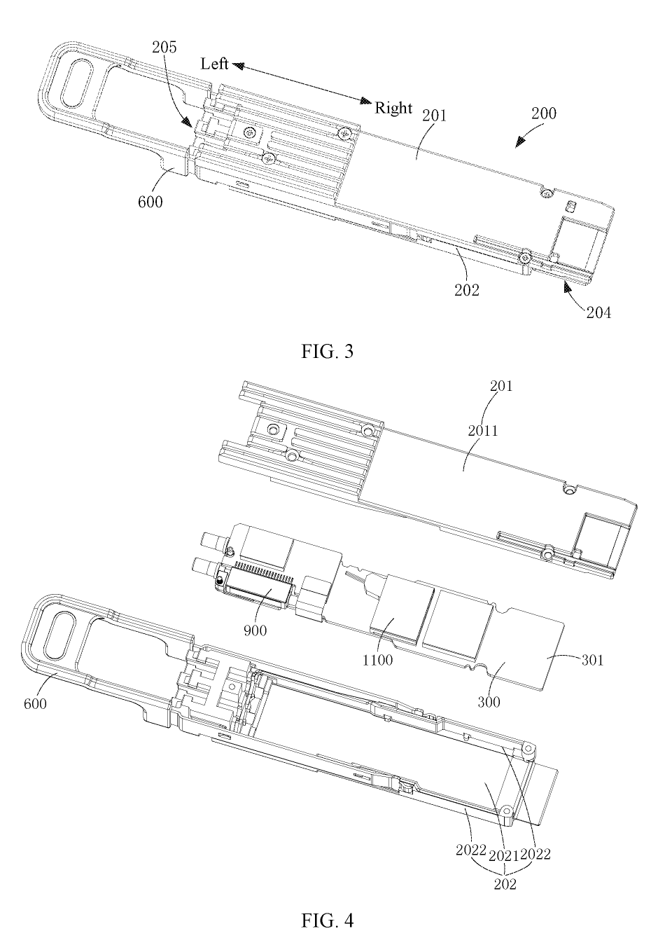

FIG. 3 is a structural diagram of an optical module provided according to some embodiments of the present disclosure, and FIG. 4 is an exploded view of an optical module provided according to some embodiments of the present disclosure. As shown in FIG. 3 and FIG. 4, the optical module 200 includes a shell, and a circuit board 300, a tunable laser 900, and a coherent optical assembly 1100 disposed in the shell.

The shell includes an upper shell 201 and a lower shell 202, where the upper shell 201 covers the lower shell 202 to form the shell with an opening 204 and an opening 205; and the outer contour of the shell is generally square.

In some embodiments, the lower shell 202 includes a bottom plate 2021 and two lower side plates 2022 located at two sides of the bottom plate 2021 and perpendicular to the bottom plate 2021; and the upper shell 201 includes a cover plate 2011, where the cover plate 2011 covers the two lower side plates 2022 of the lower shell 202 to form the shell.

In some embodiments, the lower shell 202 includes a bottom plate 2021 and two lower side plates 2022 located on two sides of the base plate 2021 and perpendicular to the bottom plate 2021; and the upper shell 201 includes a cover plate 2011 and two upper side plates located on two sides of the cover plate 2011 and perpendicular to the cover plate 2011, where the two upper side plates and the two lower side plates 2022 are combined to ensure that the upper shell 201 covers the lower shell 202.

The direction of a connecting line between the opening 204 and the opening 205 may be consistent with the length direction of the optical module 200 or may be inconsistent with the length direction of the optical module 200. For example, the opening 204 is located at the end of the optical module 200 (the right end of FIG. 3), and the opening 205 is also located at the end of the optical module 200 (the left end of FIG. 3). Alternatively, the opening 204 is located at the end of the optical module 200, and the opening 205 is located at the side of the optical module 200. The opening 204 is an electrical port, where a golden finger 301 of the circuit board 300 extends out from the opening 204 and is inserted into the electrical connector of the host computer 100. The opening 205 is an optical port, which is configured to be connected to the external optical fiber 101 such that the optical fiber 101 is connected to the tunable laser 900 and the coherent optical assembly 1100 in the optical module 200.

An assembly method of combining the upper shell 201 with the lower shell 202 is adopted, such that the circuit board 300, the tunable laser 900, the coherent optical assembly 1100, and other components can be conveniently mounted in the shell. These components can be packaged by the upper shell 201 and lower shell 202 for protection. In addition, when the circuit board 300, the tunable laser 900, the coherent optical assembly 1100, and other components are assembled, positioning components, heat dissipation components, and electromagnetic shielding components for these devices can be conveniently deployed, which is conducive to automated production.

In some embodiments, the upper shell 201 and the lower shell 202 are made of metal materials, which is conducive to electromagnetic shielding and heat dissipation.

In some embodiments, the optical module 200 further includes an unlocking component 600 located outside its shell. The unlocking component 600 is configured to achieve a fixed connection between the optical module 200 and the host computer, or to release the fixed connection between the optical module 200 and the host computer.

For example, the unlocking component 600 is located outside the two lower side plates 2022 of the lower shell 202, and includes an engaging component that matches the cage 106 of the host computer 100. When the optical module 200 is inserted into the cage 106, the optical module 200 is fixed in the cage 106 by the engaging component of the unlocking component 600; and when the unlocking component 600 is pulled, the engaging component of the unlocking component 600 moves accordingly, such that the connection relationship between the engaging component and the host computer is changed to release the fixation between the optical module 200 and the host computer, thereby pulling out the optical module 200 from the cage 106.

The circuit board 300 includes circuit traces, electronic components, and chips, where the electronic components and the chips are connected according to the circuit design through the circuit traces to implement functions such as power supply, electrical signal transmission, and grounding. The electronic components may include, for example, capacitors, resistors, transistors, and metal-oxide-semiconductor field-effect transistors (MOSFETs). The chips may include, for example, microcontroller units (MCUs), laser driving chips, transimpedance amplifiers (TIAs), limiting amplifiers, clock and data recovery (CDR) chips, power management chips, and digital signal processing (DSP) chips.

The circuit board 300 is generally a rigid circuit board. The rigid circuit board can also serve a load-bearing function because of its relatively hard material, for example, the rigid circuit board can smoothly carry the above-mentioned electronic components and chips. The rigid circuit board can also be inserted into the electrical connector in the cage 106 of the host computer 100.

The circuit board 300 further includes a golden finger 301 formed on an end surface thereof, where the golden finger 301 is composed of a plurality of mutually independent pins. The circuit board 300 is inserted into the cage 106, and the golden finger 301 is connected to the electrical connector in the cage 106. The golden finger 301 may be disposed on only one surface of the circuit board 300 (e.g., the upper surface shown in FIG. 4), or may be disposed on the upper and lower surfaces of the circuit board 300 to provide more pins, thereby adapting to scenarios requiring a large number of pins. The golden finger 301 is configured to establish an electrical connection with the host computer to achieve power supply, grounding, two-wire inter-integrated circuit (I2C) signal transmission, data signal transmission, etc. Certainly, flexible circuit boards are also used in some optical modules. Flexible circuit boards are generally used in conjunction with rigid circuit boards as a supplement to rigid circuit boards.

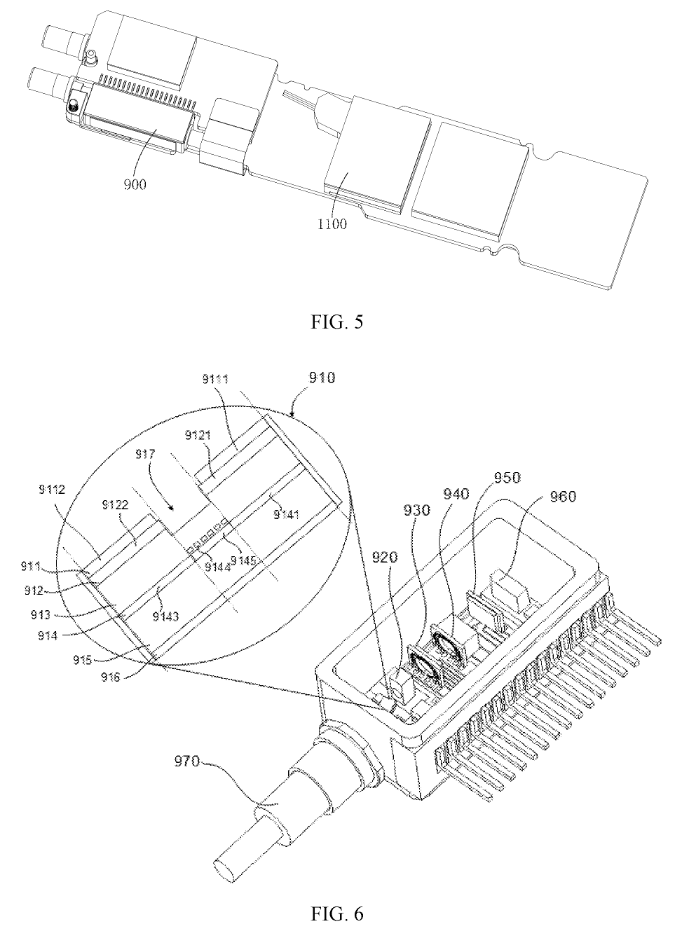

FIG. 5 is an internal structural diagram of an optical module according to some embodiments of the present disclosure. As shown in FIG. 5, in some examples of the embodiments of the present disclosure, a surface of the circuit board 300 may be provided with the tunable laser 900.

In some examples, the surface of the circuit board 300 may be provided with the coherent optical assembly 1100. The coherent optical assembly 1100 may include an optical modulation chip. The optical modulation chip is configured to modulate and demodulate optical signals.

In some examples, the optical modulation chip may be a silicon photonic chip.

In some examples, the optical modulation chip may be a thin-film lithium niobate chip.

The optical modulation chip itself does not have a light source. The tunable laser 900 is configured as an external light source for the optical modulation chip. The tunable laser 900 can emit light from a side surface, and emitted light enters the optical modulation chip, such that the optical signal is modulated by a modulator integrated in the optical modulation chip. An external optical signal enters the optical modulation chip and is then coherently demodulated with local oscillator light, thereby achieving demodulation of the optical signal.

FIG. 6 is an internal structural diagram of a tunable laser according to some embodiments of the present disclosure. As shown in FIG. 6, in some embodiments, the tunable laser 900 may include a package cavity.

In some examples, a gain chip 910 may be disposed inside the package cavity.

In some examples, a lens 920 may be disposed inside the package cavity.

In some examples, a wavelength selection assembly may be disposed inside the package cavity.

In some examples, the wavelength selection assembly may include a first filter, for example, a first etalon 930.

In some examples, the wavelength selection assembly may include a second filter, for example, a second etalon 950.

In some examples, a phase shifter 940 may be disposed inside the package cavity.

In some examples, a reflector 960 may be disposed inside the package cavity.

In some embodiments, carriers are injected into the gain chip 910, and the gain chip 910 emits light with a broad wavelength range according to the carriers. Specific currents are then input to the first etalon 930 and the second etalon 950 respectively, to heat the first etalon 930 and the second etalon 950 to specific temperatures, such that light with a specific wavelength can be filtered from broad-spectrum light, achieving wavelength selection. By supplying different currents to the wavelength selection assembly, the temperature of the wavelength selection assembly can be tuned, thereby achieving wavelength tuning.

In some examples, the light emitted by the gain chip 910 may be divergent light, so a divergent light beam emitted by the gain chip 910 is collimated into a parallel beam by the lens 920, and then enters the first etalon 930 in a form of parallel light. With the first etalon 930 being combined with the second etalon 950, light with a wavelength that can pass through the first etalon 930 and the second etalon 950 is filtered out. In some examples, with the first etalon 930 and the second etalon 950 being heated separately, light with a desired wavelength (target wavelength) can be selected based on the vernier effect of the first etalon 930 and the second etalon 950.

In some examples, the first etalon 930 and the second etalon 950 may be spaced apart to form a vernier etalon, and have different FSRs (free spectral ranges). According to a vernier principle, optical waves within common transmission passbands of the first etalon 930 and the second etalon 950 can be filtered out. That is, when specific wavelengths in the transmission spectra of the two etalons coincide (i.e., are mutually aligned), the light with the specific wavelengths can be selected.

In some embodiments, with the first etalon 930 and the second etalon 950 being respectively heated to different temperatures, refractive indices of the two etalons change accordingly, thereby changing optical path lengths of the two etalons and cavity lengths of a resonant cavity. Wavelengths selected by the two etalons changes, thereby achieving wavelength tuning.

In some embodiments, the resonant cavity of the tunable laser 900 is relatively long, and there are many possible cavity molds that can oscillate. The transmission spectrum of the filter only allows one of the cavity molds to have relatively low loss and to form laser oscillation output. Since the cavity mold is susceptible to drifting due to temperature, stress, and other factors, and the output wavelength is related to the cavity mold, this may cause the output wavelength to drift. Therefore, it is necessary to lock the specific wavelength selected by the wavelength selection assembly. In some embodiments, a temperature of the phase shifter 940 is adjusted to change a refractive index of the phase shifter 940 and an optical length of the phase shifter 940, thereby changing a cavity length of the resonant cavity to lock the cavity length of the resonant cavity, correspondingly locking the cavity mold of the resonant cavity, and further locking a wavelength.

In some embodiments, one end face of the gain chip 910 may be configured as a first resonant end face of the resonant cavity of the tunable laser 900, and the reflector 960 may be configured as a second resonant end face of the resonant cavity, where the first resonant end face and the second resonant end face form the resonant cavity. The resonant cavity has a laser mode wavelength (namely, a resonant wavelength) supported by the resonant cavity, where the laser mode may be a longitudinal mode or a transverse mode, and the laser mode wavelength is related to the length of the resonant cavity. A current wavelength is the laser mode wavelength supported by the resonant cavity, light of the current wavelength can oscillate within the resonant cavity to obtain a positive net gain, thereby ultimately forming a laser output. The current wavelength is not a wavelength supported by the resonant cavity, light cannot oscillate within the resonant cavity and eventually disappears inside the resonant cavity. A temperature of the wavelength selection assembly is tuned to adjust the length of the resonant cavity to the cavity length corresponding to the light with the specific wavelength (namely, a target wavelength), and the light with the specific wavelength selected by the wavelength selection assembly reflects and oscillates back and forth inside the resonant cavity. When a gain equals a loss, spontaneous emission light is converted into stimulated emission light, thereby forming laser output.

In some embodiments of the present disclosure, in order to increase the output optical power of the laser, a semiconductor optical amplifier may be disposed inside the package cavity. In some embodiments, an optical fiber adapter may be disposed on an outer wall of the package cavity, and the optical fiber adapter may be positioned close to the reflector 960. The semiconductor optical amplifier is disposed between the optical fiber adapter and the reflector 960. Laser formed by oscillation is amplified in optical power by the semiconductor optical amplifier, thereby increasing the output optical power of the laser. When the optical power is amplified using the semiconductor optical amplifier, the lens is disposed between a discrete gain chip and the semiconductor optical amplifier, or discrete devices are coupled via an optical fiber to achieve relatively high power output. However, interface reflection and relatively large loss inevitably occur in both lens coupling and fiber coupling, resulting in attenuation of the optical power.

In some embodiments of the present disclosure, in order to increase the output optical power of the laser and avoid discrete disposition of the gain chip and the semiconductor optical amplifier, the gain chip and the semiconductor optical amplifier may be integrated. Since one end face of the gain chip serves as the first resonant end face, a reflective film may be coated on this end face of the gain chip. As the semiconductor optical amplifier is a single-pass optical device, both end faces of the gain chip may be coated with high-transmittance films, and the waveguide may be designed with a curved and inclined structure to prevent end-face feedback light from affecting laser mode selection.

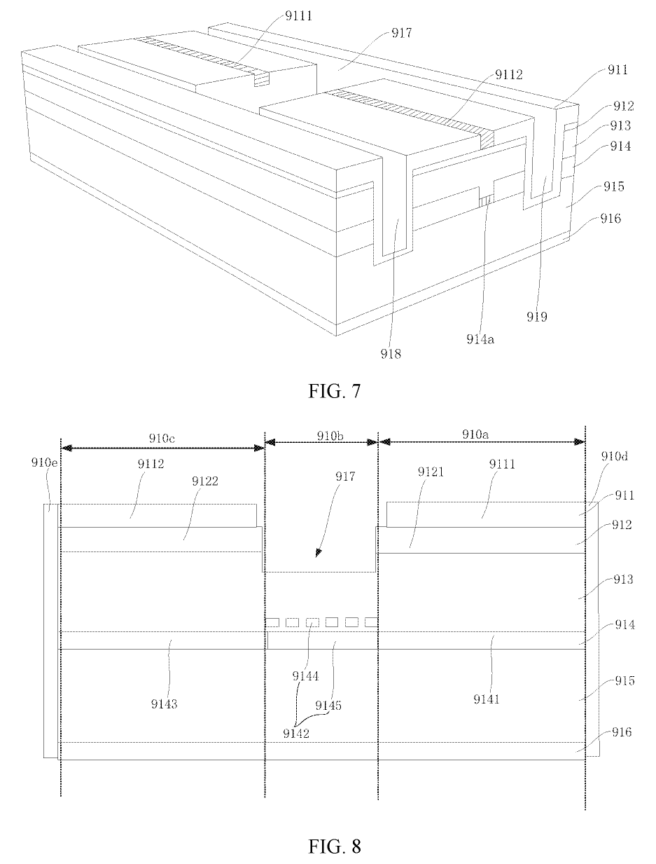

FIG. 7 is a structural diagram of a gain chip in a tunable laser according to some embodiments of the present disclosure, and FIG. 8 is a cross-sectional view of a gain chip in a tunable laser according to some embodiments of the present disclosure. As shown in FIG. 7 and FIG. 8, in some embodiments of the present disclosure, the gain chip 910 may include a top layer 911. The top layer 911 mainly serves as a protective layer. The protective layer serves as a passivation layer to provide protection against oxidation and moisture, thereby protecting the gain chip 910. An upper electrode may be formed on the surface of the top layer 911.

In some examples, the gain chip 910 may include a contact layer 912. The contact layer 912 may be located under the top layer 911. The contact layer 912 may be an ohmic contact layer, and made of InGaAs.

In some examples, the gain chip 910 may include an upper confinement layer 913. The upper confinement layer 913 may be located under the contact layer 912.

In some examples, the gain chip 910 may include a light-emitting layer 914. The light-emitting layer 914 may be located under the upper confinement layer 913.

In some examples, the gain chip 910 may include a lower confinement layer 915. The lower confinement layer 915 may be located under the light-emitting layer 914.

In some examples, the gain chip 910 may include a bottom layer 916. The bottom layer 916 may be located under the lower confinement layer 915. A lower electrode is formed on a surface of the bottom layer 916, and the upper and lower electrodes are respectively connected to positive and negative terminals of a power supply, thereby forming an electrical circuit for injection of carriers.

In some examples, the upper confinement layer 913 and the lower confinement layer 915 are respectively located on both sides of the light-emitting layer 914, and are mainly configured to provide a heterojunction to better define and confine a carrier recombination region, and to confine light within the light-emitting layer 914.

In some embodiments, the light-emitting layer 914 may include a light-emitting region 914a. The light-emitting region 914a may include a first active region 9141, a passive grating region 9142, and a second active region 9143 in sequence connected. For example, the first active region 9141 and the second active region 9143 need to be electrically biased, while the passive grating region 9142 is not electrically biased. The passive grating region 9142 may include a grating structure 9144 and a waveguide region 9145.

In some embodiments, the multi-quantum well structure layer is employed for both the first active region 9141 and the second active region 9143, thereby enhancing the capability of the active region to collect carriers and increasing radiative recombination capability.

In some embodiments, the passive grating region 9142 can achieve a flat reflection spectrum and serve as a reflector, which can serve as the first resonant end face of the laser resonant cavity to reflect the light with the specific wavelength. The wavelength range reflected by the passive grating region is affected by the refractive index of the passive grating region, and fluctuations in carrier concentration within the region affect the refractive index. To ensure stability of the effective refractive index of the passive grating region, injection of carriers into the passive grating region should be avoided. Therefore, in the present disclosure, the surface of the top layer 911 is recessed downward to form a first electrical isolation trench 917. In this case, the first electrical isolation trench 917 divides the upper electrode into a first electrode region 9111 and a second electrode region 9112, that is, the first electrical isolation trench 917 is located between the first electrode region 9111 and the second electrode region 9112. In addition, the first active region 9141 is disposed within a downward projection area of the first electrode region 9111, the second active region 9143 is disposed within a downward projection area of the second electrode region 9112, and the passive grating region 9142 is disposed within a downward projection area of the first electrical isolation trench 917. Disposition of the first electrical isolation trench 917 ensures that more carriers are effectively injected into the first active region 9141 and the second active region 9143, thereby ensuring concentrations of carriers in the first active region 9141 and the second active region 9143. In addition, disposition of the first electrical isolation trench 917 can prevent injection of carriers into the passive grating region 9142, serving an electrical isolation function, thereby avoiding injection of the carriers into the passive grating region 9142 and ensuring stability of the effective refractive index of the passive grating region 9142.

In some embodiments of the present disclosure, the bottom layer 916 may include a third electrode region, where the third electrode region and the first electrode region 9111 serve as a negative terminal and a positive terminal respectively, and the first active region 9141 is located under the first electrode region 9111, thereby enabling effective injection of the carriers into the first active region 9141. In some examples, the second active region 9143 is located under the second electrode region 9112, thereby enabling effective injection of the carriers into the second active region 9143.

In some embodiments, the contact layer 912 has high conductivity. To prevent carriers from being transferred into the passive grating region 9142 through the contact layer 912, the first electrical isolation trench 917 extends downward to the contact layer 912, thereby dividing the contact layer 912 into a first contact region 9121 and a second contact region 9122. For example, the first contact region 9121 may be located under the first electrode region 9111, and the second contact region 9122 may be located under the second electrode region 9112. In some examples, the first electrical isolation trench 917 may further extend downward to the upper confinement layer 913.

In some embodiments, the first active region 9141 may be located just under the first electrode region 9111, and the second active region 9143 may be located just under the second electrode region 9112. To prevent carriers from flowing into sides of the first active region 9141 and the second active region 9143, concentrations of the carriers respectively injected into the first active region 9141 and the second active region 9143 are reduced, and a second electrical isolation trench 918 and a third electrical isolation trench 919 may be formed on both sides of the first electrical isolation trench 917 respectively. For example, the second electrical isolation trench 918 is formed on one side of the first electrical isolation trench 917 by downward etching from the top layer 911, and the second electrical isolation trench 918 is located on one side of the light-emitting region 914a; and the third electrical isolation trench 919 is formed on the other side of the first electrical isolation trench 917 by downward etching from the top layer 911, and the third electrical isolation trench 919 is located on the other side of the light-emitting region 914a.

In some examples, lengths of the second electrical isolation trench 918 and the third electrical isolation trench 919 are consistent with a length of the gain chip 910. Respective lengths of the second electrical isolation trench 918 and the third electrical isolation trench 919 laterally cover the first active region 9141, the passive grating region 9142, and the second active region 9143. Depths of the second electrical isolation trench 918 and the third electrical isolation trench 919 s may extend downward to the upper confinement layer 913, thereby sufficiently confining output carriers within the first active region 9141 and the second active region 9143, preventing the carriers from being transferred to sides of the first active region 9141 and the second active region 9143, and ensuring the concentrations of the carriers transmitted to the first active region 9141 and the second active region 9143.

In some embodiments, the first active region 9141 may emit spontaneous emission light over a wide wavelength range based on the carriers injected from the first electrode region 9111. The temperature of the wavelength selection assembly is tuned, such that the light with the specific wavelength can be selected from the light beam emitted by the first active region 9141. The selected light with the specific wavelength undergoes reduced loss in the resonant cavity formed by the passive grating region 9142 and the reflector 960, and reflects and oscillates back and forth within the resonant cavity. When a gain equals a loss, the spontaneous emission light emitted by the first active region 9141 begins to be converted into the stimulated emission light, thereby forming laser output. The formed laser is transmitted to the second active region 9143 through the passive grating region 9142, the second active region 9143 amplifies optical power of the laser according to the injected carriers, thereby increasing the output optical power of the laser.

In some embodiments, an optical fiber adapter 970 may be disposed on an outer wall of the package cavity, and the optical fiber adapter 970 may be located on one side close to the gain chip 910. Laser light amplified by the second active region 9143 is transmitted into the optical fiber adapter 970, and then transmitted to an outside of the tunable laser 900 via the optical fiber adapter 970, thereby achieving laser emission.

In some embodiments of the present disclosure, the first electrode region 9111, the first contact region 9121, an upper confinement layer region corresponding to the first contact region 9121, the first active region 9141, and a lower confinement layer region and a third electrode region that are corresponding to the first active region 9141 are in sequence arranged from top to bottom to form a gain region 910a.

In some examples, the second electrode region 9112, the second contact region 9122, an upper confinement layer region corresponding to the second contact region 9122, the second active region 9143, a lower confinement layer region and a third electrode region that are corresponding to the second active region 9143 are in sequence arranged from top to bottom to form an optical amplification region 910c.

A grating region 910b is located between the gain region 910a and the optical amplification region 910c. In some examples of the embodiments of the present disclosure, the optical amplification region 910c is equivalent to an optical amplifier. The optical amplifier is integrated into the gain chip 910 and the gain region 910a is connected to the optical amplification region 910c via the grating region 910b, thereby achieving optical power amplification.

In some examples of the embodiments of the present disclosure, the grating region 910b can achieve a flat reflection spectrum in a C-band. Therefore, the grating region 910b serves as a first resonant end face of a resonant cavity, and the reflector 960 serves as a second resonant end face of the resonant cavity. The selected light with the specific wavelength reflects and oscillates back and forth between the grating region 910b and the reflector 960, and reflects and oscillates within the resonant cavity. When a gain equals a loss, the spontaneous emission light emitted by the first active region 9141 begins to be converted into the stimulated emission light, thereby forming laser output.

In some examples of the embodiments of the present disclosure, electrical isolation between the gain region 910a and the optical amplification region 910c is achieved via the first electrical isolation trench 917, so the gain region 910a and the optical amplification region 910c can be electrically tuned independently. For example, different currents can be supplied independently to the gain region 910a and the optical amplification region 910c.

In some embodiments of the present disclosure, both ends of the gain chip 910 are coated with a first high-transmittance film 910d and a second high-transmittance film 910e respectively. The first high-transmittance film 910d is disposed adjacent to the first active region 9141, which is conducive to increasing transmittance of light entering and exiting the first active region 9141; the second high-transmittance film 910e is disposed adjacent to the second active region 9143, which is conducive to increasing transmittance of light entering and exiting the second active region 9143.

In some examples of the embodiments of the present disclosure, the optical amplifier is integrated into the gain chip due to presence of the grating region 910b. The gain region 910a and the optical amplification region 910c are connected via the grating region 910b, and the grating region 910b provides the first resonant end face, such that the light with the specific wavelength reflects and oscillates back and forth between the grating region 910b and the reflector 960, obtaining a positive gain layer, thus forming laser. In addition, both ends of the gain chip 910 are respectively coated with a first high-transmittance film 910d and a second high-transmittance film 910e, thereby ensuring normal operation of the optical amplifier.

In the laser provided in some embodiments of the present disclosure, the second active region 9143 is integrated inside the gain chip 910 via the passive grating region 9142. The second active region 9143 can amplify the laser formed after oscillation, thereby increasing the output optical power of the laser. In addition, the first active region 9141 and the second active region 9143 are connected via the passive grating region 9142, which can reduce interface reflection and other issues compared with connection via the lens or the optical fiber. This ensures the output optical power of the laser. In some embodiments of the present disclosure, the second active region 9143 is integrated inside the gain chip 910, the second active region 9143 serves as the optical amplifier to increase the output optical power of the laser, and it is not necessary to separately provide a semiconductor optical amplifier outside the gain chip, thereby reducing a volume of the package cavity and facilitating miniaturization of the laser.

In some embodiments of the present disclosure, the first active region 9141 and the second active region 9143 are integrated on-chip through the passive grating region 9142, where the first active region 9141 serves as the gain region and the second active region 9143 serves as the optical amplifier to increase the output optical power of the laser, and an end face of the passive grating region 9142 provides an effective reflecting end face for the laser, such that it is not necessary to separately provide the semiconductor optical amplifier outside the gain chip, reducing the volume of the package cavity and facilitating the miniaturization of the laser. In addition, it is also conducive to discrete tuning of the specific and output optical power of the laser to adapt to different application environments.

In some embodiments of the present disclosure, the passive grating region 9142 may include a grating structure 9144 and a waveguide region 9145. Light with a wide wavelength range emitted by the first active region 9141 is transmitted along the waveguide region 9145. In some embodiments, an optical spot emitted by the first active region 9141 is relatively large and covers the grating structure 9144 and the waveguide region 9145 for transmission. For example, the grating structure 9144 reflects a wavelength that satisfies a Bragg condition.

In some embodiments of the present disclosure, the tunable laser is expected to achieve stable power output over a wide wavelength range. If a difference in end face reflectivity is large, this will have significant impact on thresholds, power, and SMSR of the laser at different wavelengths, and will increase a difficulty in adjusting module output power and a difference in power consumption. To this end, a passive apodized chirped grating is employed for the grating structure 9144. By transforming the grating structure, broadband reflection with uniform reflectivity within a wavelength range can be achieved, thereby achieving stable output of optical power in a waveband. A grating period of the apodized chirped grating gradually varies with A spatial position, a feedback strength changes along a direction of light propagation according to an apodization function, and a grating strength is modulated by grouping every m grating periods and retaining n high-refractive-index regions within each group of m grating periods. The reflectivity and reflection spectral width of the grating can be tuned by modifying the grating structure and the refractive index difference of the grating. For example, the grating structure is modified by adjusting values of m and n, the reflectivity and reflection spectral width of the grating can be tuned, thereby achieving broadband reflection with uniform reflectivity over the wavelength range and achieving the stable output of the optical power within the waveband.

In some embodiments of the present disclosure, a coherent optical communication system utilizes a phase of light to increase communication capacity, which requires the tunable laser 900 to have lower phase noise. From 10G to 400G communication systems, higher requirements are imposed on line width and relative intensity noise of the laser. Accordingly, the line width is reduced from 5 MHz down to 300 kHz. For a 16-QAM modulation format, the line width of the laser is required to be less than 100 kHz, and the relative intensity noise is reduced to -145 dB/Hz.

In some embodiments, the passive grating region 9142 may adopt an undoped design to reduce loss. However, some impurities are still introduced into undoped semiconductor materials in a growth process, which forms shallow donor or acceptor levels in a band gap. The semiconductor material absorbs photons and generates carriers, and the carriers are in a dynamic equilibrium state. Fluctuations in carrier concentration cause changes in the refractive index, resulting in spectral broadening of the laser, thereby affecting the line width and relative intensity noise of the laser.

In some embodiments, the grating structure 9144 and the waveguide region 9145 in the passive grating region 9142 are doped with Fe in the growth process. The doped Fe can act as a donor level to compensate for a shallow donor impurity level, thereby reducing concentrations of free carriers in the material, forming an insulating layer, and alleviating an absorption loss of the free carriers in the material. Accordingly, the output optical power of the device is improved, and the line width and relative intensity noise of the laser are reduced.

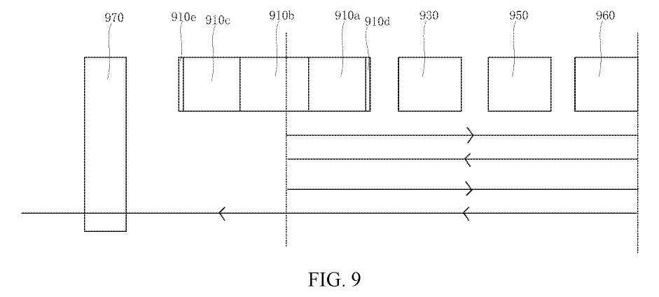

FIG. 9 is a schematic diagram of optical transmission of a tunable laser in a tunable laser according to some embodiments of the present disclosure. As shown in FIG. 9, in some embodiments of the present disclosure, the optical fiber adapter 970 is located on one side of the optical amplification region 910c. From one side where the optical fiber adapter 970 is located to the other side, the optical fiber adapter 970, the optical amplification region 910c, the grating region 910b, the gain region 910a, the wavelength selection assembly, and the reflector 960 are in sequence disposed. For example, the wavelength selection assembly may include a first etalon 930 and a second etalon 950.

The grating region 910b may serve as the first resonant end face of the resonant cavity, and the reflector 960 may serve as the second resonant end face of the resonant cavity. The gain region 910a emits a broadband light beam according to the injected carriers. The temperature of the wavelength selection assembly is tuned, such that the light with the specific wavelength is selected from the broadband light beam. The light with the specific wavelength is a target wavelength, and reflects and oscillates back and forth within the resonant cavity to obtain a positive gain, thereby forming laser. The laser formed after oscillation is transmitted to the optical fiber adapter 970 through the grating region 910b, and then transmitted to an outside of the tunable laser 900 through the optical fiber adapter 970, thus providing a light source for the coherent optical assembly.

In some embodiments, the second high-transmittance film 910e may be coated on one side, facing the optical fiber adapter 970, of the optical amplification region 910c, and the first high-transmittance film 910d may be coated on one side, facing the first etalon 930, of the gain region 910a. The first high-transmittance film 910dis disposed adjacent to the first active region 9141 in the gain region 910a, which is conducive to increasing transmittance of light entering and exiting the first active region 9141; the second high-transmittance film 910e is disposed adjacent to the second active region 9143 in the optical amplification region 910c, which is beneficial for increasing transmittance of light entering and exiting the second active region 9143.

In some embodiments of the present disclosure, both sides of the grating region 910b may be connected to the gain region 910a and the optical amplification region 910c respectively by using a butt-joint growth process, thereby integrating the optical amplifier into the gain chip to obtain a gain chip capable of outputting higher optical power.

In the laser provided by some embodiments of the present disclosure, the laser includes the package cavity, and the gain chip, the wavelength selection assembly, and the reflector are disposed within the package cavity. The gain chip includes the top layer, the bottom layer, and the light-emitting layer located between the top layer and the bottom layer, the light-emitting layer includes the light-emitting region, and the light-emitting region includes the first active region, the passive grating region, and the second active region that are in sequence connected. The top layer includes a first electrode region and a second electrode region, and a first electrical isolation trench is formed between the first electrode region and the second electrode region; the bottom layer includes a third electrode region, and the third electrode region is electrically connected to the first electrode region and the second electrode region respectively, to inject the carriers into the first active region and the second active region. The first active region is located within the downward projection area of the first electrode region and emits a broadband light beam according to injected carriers. The passive grating region includes the grating, which serves as a reflector and can serve as the first resonant end face of the laser resonant cavity to reflect the light with the specific

wavelength. A wavelength reflected by the passive grating region is related to an effective refractive index of the passive grating region, and the effective refractive index is related to a current magnitude. In order to ensure stability of the effective refractive index of the passive grating region, injection of carriers into the passive grating region should be avoided. Therefore, in the present disclosure, the passive grating region is located within the downward projection area of the first electrical isolation trench. Disposition of the first electrical isolation trench can prevent the carriers from flowing into the passive grating region, thereby providing electrical isolation and avoiding injection of the carriers into the passive grating region. The second active region is located within the downward projection area of the second electrode region. In the present disclosure, the reflector serves as the second resonant end face of the laser resonant cavity, and the first resonant end face and the second resonant end face form the resonant cavity of the laser. In the present disclosure, the light with the specific wavelength is selected from the broadband light beam output by the first active region by the wavelength selection assembly. The light with the specific wavelength reflects and oscillates back and forth within the resonant cavity to obtain the positive gain and form the laser. The formed laser is transmitted to the second active region through the passive grating region, and the second active region amplifies the laser gain according to the injected carriers, thereby increasing the output optical power of the laser. In the laser provided by the present disclosure, the second active region is integrated inside the gain chip via the passive grating region, and the second active region can optically amplify the laser formed after oscillation, thereby increasing the output optical power of the laser. In addition, the first active region and the second active region are connected via the passive grating region, which can reduce interface reflection and other issues compared with connection via the lens or the optical fiber. This ensures

the output optical power of the laser. In the present disclosure, the first active region and the second active region are integrated on-chip through the passive grating region, where the first active region serves as the gain region and the second active region serves as the optical amplifier to increase the output optical power of the laser, and an end face of the passive grating region provides an effective reflecting end face for the laser, such that it is not necessary to separately provide the semiconductor optical amplifier outside the gain chip, reducing the volume of the package cavity and facilitating the miniaturization of the laser. In addition, it is also conducive to discrete tuning of the specific and output optical power of the laser to adapt to different application environments.

A fabrication method for a laser is provided in some embodiments of the present disclosure, and applied to the above-mentioned laser, where a gain chip is packaged in the laser, so the fabrication method for the laser includes a fabrication method for the gain chip.

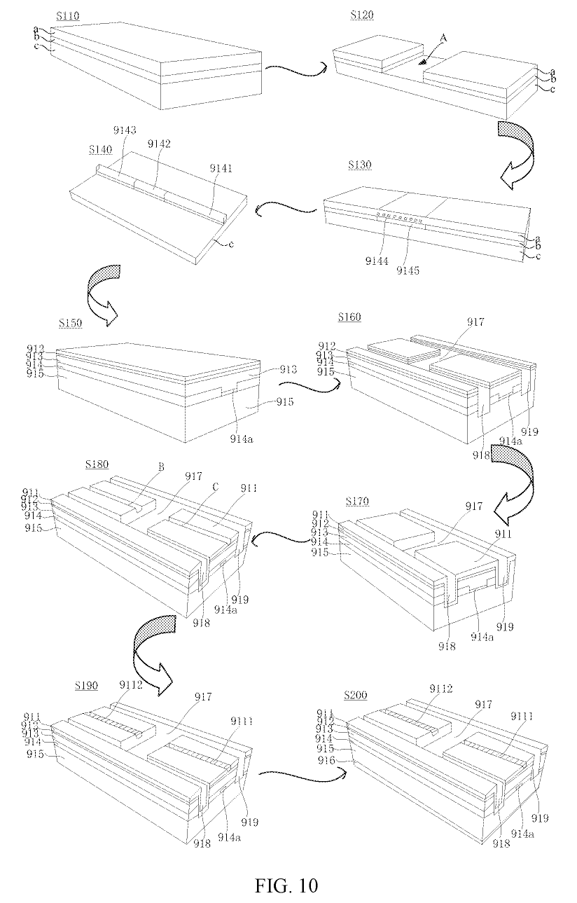

FIG. 10 is a schematic diagram of a fabrication process for a gain chip in a tunable laser according to some embodiments of the present disclosure. As shown in FIG. 10, in some embodiments of the present disclosure, the fabrication process for the gain chip 110 includes:

S110: growing, in sequence from bottom to top, a buffer layer c, a multi-quantum well structure layer b, and a cover layer a;

In some embodiments, the multi-quantum well structure layer b is encapsulated between the buffer layer c and the cover layer a. The multi-quantum well structure layer b is configured to subsequently fabricate the first active region 9141 and the second active region 9143. The multi-quantum well structure layer is employed for both the first active region 9141 and the second active region 9143, thereby enhancing the capability of the active region to collect carriers and increasing radiative recombination capability. As the number of quantum wells increases, the amount of active material increases, and the optical gain gradually increases, thereby increasing output optical power.

S120: longitudinally etching downward from a local surface of the cover layer to a surface of the buffer layer to form a void region.

In some embodiments, one side of the void region A corresponds to an optical amplification region 910c, the other side of the void region A corresponds to a gain region 910a, and the void region A corresponds to a grating region 910b. For example, the void region A is etched to facilitate subsequent growth of a passive grating region 9142.

S130: growing a passive structure on a surface of the void region A, where the passive structure includes two layers of passive waveguides; fabricating a grating structure 9144 on a surface of the passive waveguide on an upper layer; then growing a grating cladding layer on a surface of the grating structure 9144 such that the grating cladding layer is flush with a surface of the cover layer.

In some embodiments, the passive structure is grown on the surface of the void region A, where the passive structure includes two layers of InGaAsP passive waveguide structures, and upper, lower, and middle parts of the material are filled with an InP material.

In some embodiments, a passive apodized chirped grating is employed for the grating structure 9144. By transforming the grating structure, broadband reflection with uniform reflectivity within a wavelength range can be achieved, thereby achieving stable optical power output.

S140: etching downward from the surface of the cover layer to the surface of the buffer layer to form the first active region, the passive grating region, and the second active region.

In some embodiments, etching is performed downward from the surface of the cover layer to the surface of the buffer layer, and the light-emitting region 914a is retained, thereby forming the first active region 9141, the passive grating region 9142, and the second active region 9143.

S150: after forming sidewalls of the first active region, the passive grating region, and the second active region, growing sidewall current blocking layers on both sides; growing upward along surfaces of the first active region, the passive grating region, and the second active region until an upper confinement layer, a contact layer, and the top layer are in sequence formed; and continuing to grow along a bottom surface of the buffer layer until a lower confinement layer is formed.

In some embodiments, after the sidewalls of the first active region 9141, the passive grating region 9142, and the second active region 9143 are formed, the sidewall current blocking layers are grown on the both sides.

Growth is performed upward along the surfaces of the first active region 9141, the passive grating region 9142, and the second active region 9143 until the upper confinement layer, the contact layer, and the top layer are in sequence formed. Growth is further performed along the bottom surface of the buffer layer until a lower confinement layer is formed.

S160: etching downward along a projection area of the passive grating region on the top layer to form the first electrical isolation trench, where a first partition and a second partition are respectively formed on both sides of the first electrical isolation trench.

In some embodiments, etching is performed downward along the projection area of the passive grating region on the top layer to form the first electrical isolation trench 917. In addition, a second electrical isolation trench 918 and a third electrical isolation trench 919 are respectively formed on both sides of the first electrical isolation trench 917. For example, the second electrical isolation trench 918 is formed on one side of the first electrical isolation trench 917 by downward etching from the top layer 911, and the second electrical isolation trench 918 is located on one side of the light-emitting region 914a; and the third electrical isolation trench 919 is formed on the other side of the first electrical isolation trench 917 by downward etching from the top layer 911, and the third electrical isolation trench 919 is located on the other side of the light-emitting region 914a.

S170: growing a protective layer on a current top surface to form the top layer.

In some embodiments, the protective layer is grown on the current top surface, and serves as a passivation layer to provide protection against oxidation and moisture, thereby protecting the gain chip 910.

S180: forming electrode windows on surfaces of the first partition and the second partition respectively.

In some embodiments, the electrode windows B and C are formed on the surfaces of the first partition and the second partition respectively.

S190: fabricating electrodes on surfaces of the electrode windows to form a first electrode region and a second electrode region respectively.

In some embodiments, the electrodes are fabricated on the surfaces of the electrode windows B and C to form the first electrode region 9111 and the second electrode region 9112 respectively.

S200: fabricating electrodes on a bottom surface of the lower confinement layer to form the third electrode region.

In some embodiments, the bottom surface of the lower confinement layer 915 is thinned and then the electrodes are fabricated to form the third electrode region. The third electrode region is located at a bottom layer of the laser.

The third electrode region is electrically connected to the first electrode region 9111, and the first active region 9141 is located under the first electrode region 9111, thereby enabling effective injection of the carriers into the first active region 9141. Similarly, the third electrode region is electrically connected to the second electrode region 9112, and the second active region 9143 is located under the second electrode region 9112, thereby enabling effective injection of the carriers into the second active region 9143.

In some embodiments of the present disclosure, both ends of the gain chip 910 are coated with a first high-transmittance film 910d and a second high-transmittance film 910e respectively. The first high-transmittance film 910dis disposed adjacent to the first active region 9141, which is conducive to increasing transmittance of light entering and exiting the first active region 9141; the second high-transmittance film 910e is disposed adjacent to the second active region 9143, which is conducive to increasing transmittance of light entering and exiting the second active region 9143.

In the tunable laser provided by the present disclosure, the grating region is located between a gain region and the optical amplification region. The optical amplification region functions as an optical amplifier. The optical amplifier is integrated into the gain chip and the gain region is connected to the optical amplification region via the grating region, thereby achieving optical power amplification to output higher optical power.

In the present disclosure, the grating region can achieve a flat reflection spectrum over a broad wavelength range. Therefore, the grating region serves as a first resonant end face of a resonant cavity, and a reflector serves as a second resonant end face of the resonant cavity. Selected light with a specific wavelength reflects and oscillates between the grating region and the reflector. When a gain exceeds a loss, spontaneous emission light from the first active region is converted into stimulated emission light, thereby forming laser output. The formed laser is transmitted to the second active region through the passive grating region, and the second active region amplifies optical power of the laser according to the injected carriers, thereby increasing the output optical power of the laser.

In the present disclosure, electrical isolation between the gain region and the optical amplification region is achieved via the first electrical isolation trench, so the gain region and the optical amplification region can be tuned independently. For example, different currents can be supplied independently to the gain region and the optical amplification region.

The above descriptions are merely specific embodiments of the present disclosure, but the scope of protection of the present disclosure is not limited thereto. Any of those skilled in the art can think of changes or substitutions within the technical scope of the present disclosure, and these changes or substitutions shall all be included within the scope of protection of the present disclosure. Therefore, the scope of protection of the present disclosure shall be subject to the scope of protection of the claims.

What is claimed is:

1. A laser, comprising a package cavity, wherein the package cavity is internally provided with:
a gain chip, comprising:
a top layer, comprising a first electrode region and a second electrode region, wherein a first electrical isolation trench is formed between the first electrode region and the second electrode region;
a bottom layer, comprising a third electrode region, wherein the third electrode region is electrically connected respectively to the first electrode region and the second electrode region to output carriers; and
a light-emitting layer, located between the top layer and the bottom layer, and comprising a light-emitting region, wherein the light-emitting region comprises in sequence connected:
a first active region, located within a downward projection area of the first electrode region to receive the carriers, and configured to emit a broadband light beam according to injected carriers;
a passive grating region, located within a downward projection area of the first electrical isolation trench, comprising a grating structure and a waveguide region, and configured to provide a first resonant end face for the laser; and
a second active region, located within a downward projection area of the second electrode region to receive the carriers;
a wavelength selection assembly, disposed outside the gain chip, located on one side close to the first active region, and configured to select light with a specific wavelength from the light beam emitted by the first active region; and
a reflector, disposed on one side, away from the gain chip, of the wavelength selection assembly, and configured to provide a second resonant end face for the laser, such that a resonant cavity is formed between the passive grating region and the reflector; and
the light beam emitted from the first active region is filtered by the wavelength selection assembly to select the light with the specific wavelength, the light with the specific wavelength oscillates in the resonant cavity to form laser, the laser is transmitted to the second active region through the passive grating region, and the second active region optically amplifies the laser according to the injected carriers.

2. The laser according to claim 1, wherein a contact layer and an upper confinement layer are formed from top to bottom between the top layer and the light-emitting layer;
a lower confinement layer is formed between the light-emitting layer and the bottom layer; and
the first electrical isolation trench extends downward to the contact layer, such that the contact layer is divided into a first contact region and a second contact region, the first contact region is located under the first electrode region, and the second contact region is located under the second electrode region.

3. The laser according to claim 1, wherein a second electrical isolation trench is formed on one side of the first electrical isolation trench by downward etching from the top layer, and the second electrical isolation trench is located on one side of the light-emitting region; and
a third electrical isolation trench is formed on the other side of the first electrical isolation trench by downward etching from the top layer, and the third electrical isolation trench is located on the other side of the light-emitting region.

4. The laser according to claim 1, wherein the grating structure comprises an apodized chirped grating.

5. The laser according to claim 1, wherein a first high-transmittance film and a second high-transmittance film are respectively coated on both end faces of the gain chip.

6. The laser according to claim 5, wherein the first high-transmittance film is disposed adjacent to the first active region to increase transmittance of light entering and exiting the first active region.

7. The laser according to claim 5, wherein the second high-transmittance film is disposed adjacent to the second active region to increase transmittance of light entering and exiting the second active region.

8. The laser according to claim 2, wherein the gain chip comprises a gain region and an optical amplification region;
the gain region comprises, in sequence from top to bottom, the first electrode region, the first contact region, an upper confinement layer region corresponding to the first contact region, the first active region, and a lower confinement layer region and a third electrode region that are corresponding to the first active region;
the optical amplification region comprises, in sequence from top to bottom, the second electrode region, the second contact region, an upper confinement layer region corresponding to the second contact region, the second active region, and a lower confinement layer region and a third electrode region that are corresponding to the second active region; and
the gain region and the optical amplification region are capable of being electrically tuned independently.

9. The laser according to claim 1, wherein an optical fiber adapter is disposed on an outer wall of the package cavity, and the optical fiber adapter is located on one side of the second active region; and
light amplified by the second active region is output through the optical fiber adapter.

10. The laser according to claim 9, wherein along one side of the package cavity to the other side thereof, the optical fiber adapter, the gain chip, the wavelength selection assembly, and the reflector are respectively disposed; and
the second active region is closer to the optical fiber adapter than the grating region.

11. The laser according to claim 1, wherein the package cavity is further internally provided with:
a phase shifter, wherein the phase shifter is configured to change a cavity length of the resonant cavity based on temperature regulation to lock a wavelength; and
the wavelength selection assembly comprises a first etalon and a second etalon, and the phase shifter is disposed between the first etalon and the second etalon.

12. The laser according to claim 11, wherein the package cavity is further internally provided with:
a lens, disposed between the first etalon and the gain chip, the lens is configured to collimate a divergent light beam emitted by the gain chip into a parallel light beam and transmit the parallel light beam to the first etalon.

13. The laser according to claim 1, wherein
the passive grating region is doped with Fe in a growth process, and doped Fe serves as a donor level to compensate for a shallow donor impurity level.

14. The laser according to claim 1, wherein a multi-quantum well structure is employed for the first active region and the second active region.

15. The laser according to claim 2, wherein the contact layer comprises an ohmic contact layer formed of an InGaAs material.

16. A fabrication method for a laser, applied to the laser according to claim 1, wherein a gain chip is packaged within the laser, the fabrication method comprises a fabrication method for the gain chip, and the fabrication method for the gain chip comprises:
growing, in sequence from bottom to top, a buffer layer, a multi-quantum well structure layer, and a cover layer;
longitudinally etching downward from a local surface of the cover layer to a surface of the buffer layer to form a void region;
growing a passive structure on a surface of the void region, wherein the passive structure comprises two layers of passive waveguides; fabricating a grating structure on a surface of the passive waveguide on an upper layer; then growing a grating cladding layer on a surface of the grating structure such that the grating cladding layer is flush with a surface of the cover layer;
etching downward from the surface of the cover layer to the surface of the buffer layer to respectively form the first active region, the passive grating region, and the second active region;
after forming sidewalls of the first active region, the passive grating region, and the second active region, growing sidewall current blocking layers on both sides; growing upward along surfaces of the first active region, the passive grating region, and the second active region until an upper confinement layer, a contact layer, and the top layer are in sequence formed; and continuing to grow along a bottom surface of the buffer layer until a lower confinement layer is formed;
etching downward along a projection area of the passive grating region on the top layer to form the first electrical isolation trench, wherein a first partition and a second partition are respectively formed on both sides of the first electrical isolation trench;
forming electrode windows on surfaces of the first partition and the second partition, and fabricating electrodes to respectively form a first electrode region and a second electrode region; and
fabricating electrodes on a bottom surface of the lower confinement layer to form the third electrode region.

17. The fabrication method according to claim 16, wherein when the first electrical isolation trench is formed, a second electrical isolation trench is formed on one side of the first electrical isolation trench by downward etching from the top layer, and the second electrical isolation trench is located on one side of the light-emitting layer; and
a third electrical isolation trench is formed on the other side of the first electrical isolation trench by downward etching from the top layer, and the third electrical isolation trench is located on the other side of the light-emitting layer.

18. The fabrication method according to claim 16, wherein after the third electrode region is formed, a first high-transmittance film and a second high-transmittance film are respectively coated on both end faces of the gain chip.

19. The fabrication method according to claim 16, wherein the passive waveguide comprises an InGaAsP passive waveguide structure.

20. The fabrication method according to claim 16, wherein a passive apodized chirped grating is employed for the grating structure.
